(19) United States
(12) Patent Application Publication
(10) Pub. No.: US 2026/0344508 A1
(43) Pub. Date: Oct. 29, 2026

(54) POWER DELIVERY AND COOLING OF 3D STACKED MULTI-CHIPLET MODULES

(71) Applicant: INTERNATIONAL BUSINESS MACHINES CORPORATION, ARMONK, NY (US)

(72) Inventors: John Knickerbocker, Monroe, NY (US); Mukta Ghate Farooq, Hopewell Junction, NY (US); Keiji Matsumoto, Yokohama-shi (JP); John W. Golz, Hopewell Junction, NY (US)

(21) Appl. No.: 19/187,947

(22) Filed: Apr. 23, 2025

(51) Int. Cl. H10W 90/00; H10W 90/20; H10W 90/22

(52) U.S. Cl. CPC H10W 90/00; H10W 90/22; H10W 90/288; H10W 90/291; H10W 90/297; H10W 90/722; H10W 90/724

(57) ABSTRACT

A semiconductor device includes a substrate, a heat conducting layer having a redistribution layer (RDL) and a heat spreader, and a plurality of chip stacks over the substrate and disposed in the heat conducting. The heat conducting layer is configured to deliver power to the plurality of chip stacks and cool down the plurality of chip stacks.

### BACKGROUND

### Technical Field

The present disclosure generally relates to semiconductors, and more particularly, to power delivery and cooling for 3-dimensional chiplet stack structure, and methods of creation thereof.

### Description of Related Art

The continuous miniaturization of transistors and their increasing density on chips epitomize the semiconductor industry’s innovation, largely adhering to Moore’s Law. This trend has led to transistors shrinking to nanometer scales, allowing millions and even billions to fit on a single chip, significantly enhancing computational power and energy efficiency. The evolution towards system-on-chip architectures integrates various functionalities, including processing and sensing, on one chip.

### SUMMARY

According to an embodiment, a semiconductor device includes a substrate, a heat conducting layer having a redistribution layer (RDL) and a heat spreader, and a plurality of chip stacks over the substrate and disposed in the heat conducting. The heat conducting layer is configured to delivery power to the plurality of chip stacks and cool down the plurality of chip stacks.

In one embodiment, the heat conducting layer includes at least one of: diamond, diamond like carbon (DLC), graphite, a dielectric material, a ceramic, a metal, a conductive film, and a composite.

In one embodiment, the semiconductor device includes at least one power delivery structure to power at least one of the plurality of chip stacks. The at least one power delivery structure is located over the substrate and adjacent to the plurality of chip stacks.

In one embodiment, the semiconductor device includes power delivery structures located at a periphery of semiconductor device, and the at least one power delivery structure includes at least one of: through silicon vias (TSVs), vertical connections, input/output bumps, or pillars.

In one embodiment, the semiconductor device includes a heatsink layer over the conducting layer.

In one embodiment, the heatsink contacts the heat spreader and the RDL.

In one embodiment, the RDL includes at least one of: silicon dioxide, silicon nitride, silicon oxynitride, boron nitride, aluminum nitride, beryllium oxide, diamond, diamond-like carbon film, diamond-like carbon layer, or a thermal conducting material with a thermal conductivity of at least 5 w/mK.

In one embodiment, the heat spreader at least one of: Si, Cu, Ni, W, Mo, Al, Au, Pt, Pd, graphite, or a multilayered combination of metal conductors with a thermal conductivity of greater than 10 w/MK. In one embodiment, the heat spreader at least one of: AlN and a multilayered combination of ceramics with a thermal conductivity of greater than 10 w/MK. In one embodiment, the heat spreader includes microchannels.

In one embodiment, the power delivery structures are made of at least one of: Si, ceramic, Tungsten, Molybdenum, or Invar.

In one embodiment, the power delivery structures include first microchannels.

In one embodiment, the RDL is electrically connected to the substrate, the substrate is located below one chip of the plurality of chip stacks or at a peripheral of the chip, and the substrate has a laminate structure.

In one embodiment, the substrate provides ground to the plurality of chip stacks.

In one embodiment, the substrate includes at least one of: a metal core or embedded graphite sheets.

In one embodiment, the semiconductor device is encapsulated with an underfill, and the underfill is a thermal conductive material.

In one embodiment, the underfill includes second microchannels.

In one embodiment, the semiconductor device includes a thermal interface material (TIM) over the plurality of chip stacks.

In one embodiment, the plurality of chip stacks includes at least one of: transistors, coils, magnetic layers, decoupling capacitors, electrical conductor elements, or thermal conducting elements.

In one embodiment, the at least one power delivery structure includes inductors, power delivery circuits, signal delivery circuits, electrical shielding, magnetic shielding, or cooling structures.

In one embodiment, the semiconductor device includes electrical and optical communication links, and the electrical and optical communication links are located in at least one of: an interposer, a cooling unit, or a power feed unit, and the plurality of chip stacks includes at least one of: a memory, a pass-throughs of power line, or a pass-through of signal line.

According to an embodiment, a method for fabrication of a semiconductor device includes forming a substrate, forming a heat conducting layer comprising a redistribution layer (RDL) and a heat spreader, forming a plurality of chip stacks disposed in the heat conducting layer, and configuring the heat conducting layer to deliver power to the chip stacks and cool down the plurality of chip stacks.

According to an embodiment, a semiconductor device includes a plurality of chip stacks, a peripheral power delivery interconnect chiplet surrounding one side of the plurality of chip stacks, and a heat sink disposed on the plurality of chip stacks.

In one embodiment, the plurality of chip stacks are disposed in a heat conducting material. The heat conducting material includes microchannels configured to carry a flow of heat dissipating material, and the heat dissipating material is a gas or a liquid.

These and other features will become apparent from the following detailed description of illustrative embodiments thereof, which is to be read in connection with the accompanying drawings.

### BRIEF DESCRIPTION OF THE DRAWINGS

The drawings are of illustrative embodiments. They do not illustrate all embodiments. Other embodiments can be used in addition or instead. Details that can be apparent or unnecessary can be omitted to save space or for more effective illustration. Some embodiments can be practiced with additional components or steps and/or without all the components or steps that are illustrated. When the same numeral appears in different drawings, it refers to the same or like components or steps.

FIG. 1 illustrates a semiconductor device, consistent with some embodiments.

FIGS. 2A-2E illustrate a semiconductor device with microchannels in various locations.

FIG. 3 illustrates a semiconductor device with heat spreader, in accordance with some embodiments.

FIG. 4 illustrates the initial semiconductor device, in accordance with some embodiments.

FIG. 5 illustrates the semiconductor device after bumping for the interconnect, in accordance with some embodiments.

FIG. 6 illustrates the semiconductor device after assembling the heat spreader with RDL, in accordance with some embodiments.

FIG. 7 illustrates the semiconductor device after the formation of the underfill, in accordance with some embodiments.

FIG. 8 illustrates the semiconductor device after forming microchannels, in accordance with some embodiments

FIG. 9 illustrates the semiconductor device after forming a hole, in accordance with some embodiments.

FIG. 10 illustrates the semiconductor device after formation of underfill, in accordance with some embodiments.

FIG. 11 illustrates the semiconductor device after assembling additional chips, in accordance with some embodiments.

FIG. 12 illustrates the semiconductor device after assembling additional bumpers, in accordance with some embodiments.

FIG. 13 illustrates the semiconductor device after formation of additional underfill, in accordance with some embodiments.

FIGS. 14-16 illustrate repeating the steps as shown in FIGS. 8-13 to fabricate the semiconductor device with the desired number of chips.

FIG. 17 illustrates the semiconductor device after repeating fabrication acts.

FIG. 18 illustrates a block diagram of a method for forming the semiconductor device, in accordance with some embodiments.

### DETAILED DESCRIPTION

### Overview

In the following detailed description, numerous specific details are set forth by way of examples to provide a thorough understanding of the relevant teachings. However, it should be apparent that the present teachings can be practiced without such details. In other instances, well-known methods, procedures, components, and/or circuitry have been described at a relatively high-level, without detail, to avoid unnecessarily obscuring aspects of the present teachings.

In one aspect, spatially related terminology such as “front,” “back,” “top,” “bottom,” “beneath,” “below,” “lower,” above,” “upper,” “side,” “left,” “right,” and the like, is used with reference to the orientation of the Figures being described. Since components of embodiments of the disclosure can be positioned in a number of different orientations, the directional terminology is used for purposes of illustration and is in no way limiting. Thus, it will be understood that the spatially relative terminology is intended to encompass different orientations of the device in use or operation in addition to the orientation depicted in the figures. For example, if the device in the figures is turned over, elements described as “below” or “beneath” other elements or features would then be oriented “above” the other elements or features. Thus, for example, the term “below” can encompass both an orientation that is above, as well as below. The device can be otherwise oriented (rotated 90 degrees or viewed or referenced at other orientations) and the spatially relative descriptors used herein should be interpreted accordingly.

As used herein, the terms “lateral” and “horizontal” describe an orientation parallel to a first surface of a chip.

As used herein, the term “vertical” describes an orientation that is arranged perpendicular to the first surface of a chip, chip carrier, or semiconductor body.

As used herein, the terms “coupled” and/or “electrically coupled” are not meant to mean that the elements must be directly coupled together—intervening elements can be provided between the “coupled” or “electrically coupled” elements. In contrast, if an element is referred to as being “directly connected” or “directly coupled” to another element, there are no intervening elements present. The term “electrically connected” refers to a low-ohmic electric connection between the elements electrically connected together.

Although the terms first, second, etc., can be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

Example embodiments are described herein with reference to cross-sectional illustrations that are schematic illustrations of idealized or simplified embodiments (and intermediate structures). As such, variations from the shapes of the illustrations as a result, for example, of manufacturing techniques and/or tolerances, can be expected. Thus, the regions illustrated in the figures are schematic in nature and their shapes do not necessarily illustrate the actual shape of a region of a device and do not limit the scope.

It is to be understood that other embodiments can be used and structural or logical changes can be made without departing from the spirit and scope defined by the claims. The description of the embodiments is not limiting. In particular, elements of the embodiments described hereinafter can be combined with elements of different embodiments.

According to an embodiment, a semiconductor device includes a substrate, a heat conducting layer having a redistribution layer (RDL) and a heat spreader, and a plurality of chip stacks over the substrate and disposed in the heat conducting. The heat conducting layer is configured to deliver power to the plurality of chip stacks and cool down the plurality of chip stacks. This can result in an efficient cooling of the 3D stacked multi-chiplet structure.

In one embodiment, the heat conducting layer includes at least one of: diamond, diamond like carbon (DLC), graphite, a dielectric material, a ceramic, a metal, or a conductive film. Such materials can facilitate the heat dissipation from the semiconductor device.

In one embodiment, the semiconductor device includes at least one power delivery structure to power at least one of the plurality of chip stacks. The at least one power delivery structure is located over the substrate and adjacent to the plurality of chip stacks. The conducting layer can provide both the power and the heat dissipation.

In one embodiment, the semiconductor device includes power delivery structures located at a periphery of semiconductor device, and the power delivery structures includes at least one of: through silicon vias (TSVs), vertical connections, input/output bumps, or pillars. The power delivery structures include various components to provide power to the chip stacks.

In one embodiment, the semiconductor device includes a heatsink layer over the conducting dielectric layer. The heatsink layer can facilitate the overall heat dissipation from one side.

In one embodiment, the heatsink contacts the heat spreader and the RDL. The connected heatsink, RDL and heat spreader together can dissipate the heat from the semiconductor device.

In one embodiment, the RDL includes at least one of: silicon dioxide, silicon nitride, silicon oxynitride, boron nitride, aluminum nitride, beryllium oxide, diamond, diamond-like carbon film, diamond-like carbon layer, or a thermal conducting material with a thermal conductivity of at least 5 w/mK. Various suitable materials are used as RDL.

In one embodiment, the heat spreader at least one of: Si, Cu, Ni, W, Mo, Al, Au, Pt, Pd, or a multilayered combination of metal conductors with a thermal conductivity of greater than 10 w/MK. In one embodiment, the heat spreader at least one of: AlN and a multilayered combination of ceramic conductors with a thermal conductivity of greater than 10 w/MK. Various suitable materials are used as heat spreader In one embodiment, the heat spreader includes microchannels.

In one embodiment, the power delivery structures are made of at least one of: Si, ceramic, Tungsten, Molybdenum, or Invar. Various suitable materials are used as power delivery structures.

In one embodiment, the power delivery structures include first microchannels. The microchannels enhance the rate of heat dissipation.

In one embodiment, the RDL is electrically connected to the substrate, the substrate is located below one chip of the plurality of chip stacks or at a peripheral of the chip, and the substrate has a laminate structure. The substrate provides mechanical support for the semiconductor device and its components.

In one embodiment, the substrate connects the semiconductor device to the ground to the plurality of chip stacks. The laminate can further help in delivering power to various components of the semiconductor device.

In one embodiment, the substrate includes at least one of: a metal core and embedded graphite sheets. Various suitable materials can be used as the laminate.

In one embodiment, the semiconductor device is encapsulated with an underfill, and the underfill is a thermal conductive material. The underfill further helps in dissipating the heat from the semiconductor device.

In one embodiment, the underfill includes second microchannels. The microchannels enhance the rate of heat dissipation.

In one embodiment, the semiconductor device includes a thermal interface material (TIM) over the plurality of chip stacks. TIM can enhance the heat dissipation.

In one embodiment, the plurality of chip stacks includes at least one of: transistors, coils, magnetic layers, decoupling capacitors, electrical conductor elements, or thermal conducting elements. Various types of semiconductor devices can be inserted into the stack.

In one embodiment, the power delivery structures include inductors, power delivery circuits, signal delivery circuits, electrical shielding, magnetic shielding, and cooling structures. Power delivery structure works to supply power to the stack.

In one embodiment, the semiconductor device includes electrical and optical communication links, and the electrical and optical communication links are located in at least one of: an interposer, a cooling unit, or a power feed unit, and the plurality of chip stacks includes at least one of: a memory, a pass-throughs of power line, or a pass-through of signal line. The electrical and optical physical layers can be inserted into the device.

According to an embodiment, a method for fabrication of a semiconductor device includes forming a substrate, forming a heat conducting layer having a redistribution layer (RDL) and a heat spreader, forming a plurality of chip stacks disposed in the heat conducting layer, and configuring the heat conducting layer to deliver power and cool down the plurality of chip stacks. This can result in an efficient cooling of the 3D stacked multi-chiplet structure.

According to an embodiment, a semiconductor device includes a plurality of chip stacks, a peripheral power delivery interconnect chiplet surrounding one side of the plurality of chip stacks, and a micromechanical heat sink disposed on the plurality of chip stacks. The heat dissipation can help to eliminate the adverse effect of high temperature on the operability of the system. This can result in an efficient cooling of the 3D stacked multi-chiplet structure.

In one embodiment, the plurality of chip stacks are disposed in a heat conducting material. The heat conducting material includes microchannels configured to carry a flow heat dissipating material, and the heat dissipating material is a gas or a liquid. Various types of semiconductor devices can be inserted into the stack.

One of the primary challenges in power delivery is managing the complexity of voltage and IR drops. As power traverses through multiple layers of a 3D stack, resistance in interconnects can cause significant voltage drops, which can impact both performance and reliability. The increased power density typical of stacked chiplets leads to higher local power consumption, which exacerbates issues of voltage drop and can increase electromagnetic interference. Designing power distribution networks (PDNs) for these architectures adds another layer of complexity. PDNs must account for the vertical and horizontal distribution of power across densely packed chiplets while reducing (e.g., minimizing) impedance and ensuring stability. This often requires innovative approaches to PDN design to handle the increased density without compromising on the efficiency and effectiveness of power delivery.

Regarding cooling, the challenges are equally daunting. Increased power density results in thermal hotspots that can degrade performance and accelerate device wear and failure. Managing the thermal profile of the device is complicated by uneven heat distribution across different layers in the stack, with traditional cooling solutions such as heat sinks and fans often proving inadequate. Advanced cooling techniques, including liquid cooling or embedded cooling layers, are required but can be complex and costly to implement.

Disclosed are a device and methods thereof where 3D stacked multi-chiplets are embedded within a heat dielectric material. This approach seeks to address both the power delivery and cooling challenges inherent in 3D stacked architectures. By embedding the chiplets within a heat-conducting dielectric material, the system helps to reduce IR drop across the stack. The heat conducting material can enhance the electrical conductivity of the PDN, reducing (e.g., minimizing) resistance and helping to deliver power more uniformly. This also simplifies the PDN design, reducing complexity and the potential for power integrity issues.

In terms of cooling, the heat-conducting material enhances thermal conduction away from the chiplets and helps distribute heat more evenly across the device, aiding in the dissipation of heat more effectively and reducing thermal hotspots. This not only enhances device performance but also prolongs the lifespan of the components. The compatibility of this system with advanced cooling solutions, such as liquid cooling channels or microfluidic cooling, is maintained. Additionally, embedding chiplets within a heat conducting material simplifies the manufacturing process by reducing the number of separate components that need to be aligned and connected, which further enhances the mechanical stability of the stack, protecting the internal components from physical stresses and strains.

The semiconductor device is intricately designed to optimize both power delivery and thermal management within a compact structure, making it particularly suited for advanced 3D stacked multi-chiplet systems. The device includes a substrate and a heat conducting layer that houses a redistribution layer (RDL) and a heat spreader, with multiple chip stacks embedded within the heat conducting layer. The primary function of the heat conducting layer is to effectively distribute power across the device while simultaneously managing heat dissipation. This dual function ensures an efficient cooling process, vital for maintaining the reliability and performance of the 3D stacked multi-chiplet structure.

Accordingly, the teachings herein provide methods and systems of power delivery and cooling for 3-dimensional chiplet stack structure. The techniques described herein can be implemented in a number of ways. Example implementations are provided below with reference to the following figures.

Example Power Delivery and Cooling for 3-Dimensional Chiplet Stack Structure

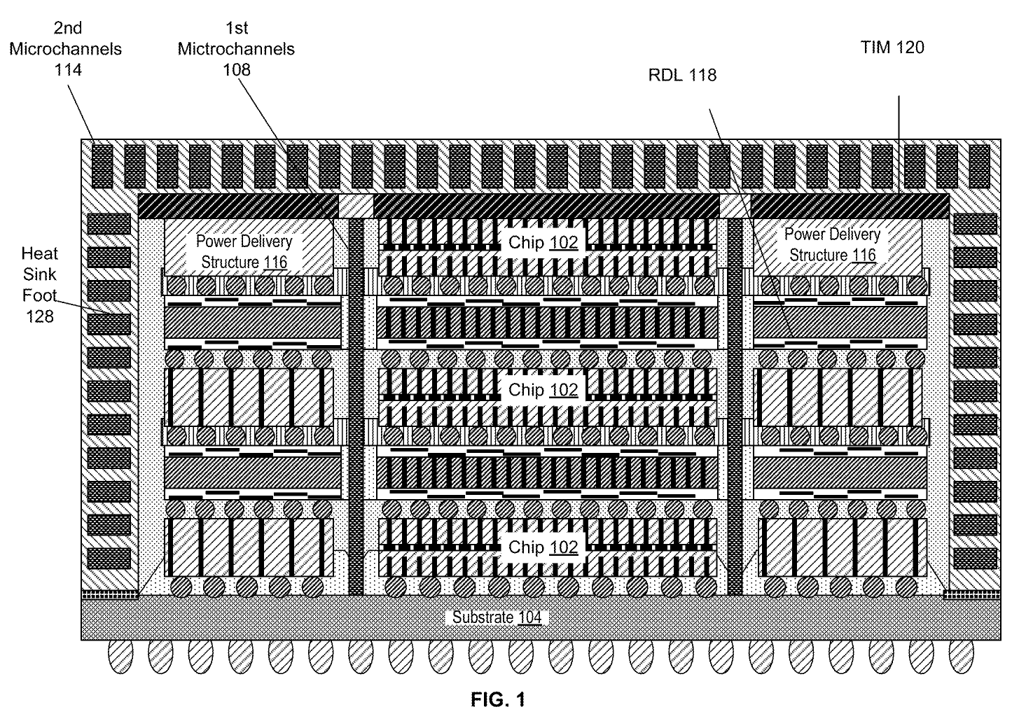

Reference now is made to FIG. 1, which is a simplified cross-sections view of a semiconductor device, consistent with an illustrative embodiment. In some embodiments, a semiconductor device includes a plurality of chip stacks 102 situated over a substrate 104. The plurality of chip stacks 102 can be embedded within a heat conducting dielectric material, e.g., heat conducting material, enhancing the thermal management capabilities of the device by improving heat distribution across the chip stacks.

In some embodiments, the RDL and the heat spreader form a heat conducting layer. The heat conducting layer includes materials such as diamond, diamond-like carbon (DLC), graphite, ceramic, various dielectric materials, metals, conductive films, and composites. These materials are selected for their superior heat dissipation properties, facilitating the removal of heat from the semiconductor device efficiently. In some embodiments, the semiconductor device includes an electrical conducting layer made of copper and a thermal conductor layer within at least one power delivery layer. This configuration delivers power to the chip stacks and aids in dissipating heat, thereby serving a dual purpose of enhancing the device's overall functionality.

In some embodiments, the heat conducting material enveloping the plurality of chip stacks 102 is integrated with first microchannels 108. The first microchannels 108 are structured to facilitate the movement of a heat dissipating material through them, effectively transporting heat away from the chip stacks to prevent overheating.

In some embodiments, the first microchannels 108 are configured to carry a flow of heat dissipating material which can be either a gas or a liquid, depending on the specific cooling requirements and the operational environment of the semiconductor device. Such a configuration allows for versatile thermal management strategies that can be adapted based on thermal load and device architecture.

In some embodiments, the semiconductor device is equipped with a heat sink positioned on the side of the plurality of chip stacks 102 opposite to the substrate 104. This heat sink includes second microchannels 114, which provide additional pathways for heat dissipation, enhancing the cooling efficiency beyond what the embedded microchannels in the dielectric material offer.

In some embodiments, the semiconductor device includes a power delivery structure 116 located within the plurality of chip stacks 102. The structure facilitates efficient distribution of power throughout the device, which facilitates maintaining stable operation across all components. The substrate 104 can be composed of various materials, including glass, silicon, an organic electrically insulating material, or an inorganic electrically insulating material, each chosen based on the specific performance and fabrication requirements of the device. In some embodiments, the substrate is a multilayer substrate, e.g., a laminate.

The power delivery structure 116 can be located at the periphery of the semiconductor device. The power delivery structure can consist of components such as through silicon vias (TSVs), vertical connections, input/output bumps, and pillars, all designed to efficiently provide power to the chip stacks. In some embodiments, the power delivery structure 116 can be made from materials such as silicon, ceramic, tungsten, molybdenum, and Invar. These materials are chosen for their robustness and their ability to withstand the thermal and mechanical stresses encountered during device operation. Additionally, in some embodiments, the first microchannels are incorporated within the power delivery structures to enhance heat dissipation, ensuring that the device operates within safe thermal limits.

In some embodiments, the semiconductor device is based on a substrate that is electrically connected to the RDL. The substrate can be positioned below one of the chip stacks or at the periphery of the chip, and can be a laminate substrate used for power and ground connections. The laminate substrate can consist of multiple layers of materials such as silicon or insulators. This substrate provides essential mechanical support and helps with the electrical management of the device. Furthermore, in some embodiments, the semiconductor device is encapsulated with an underfill that includes second microchannels for enhanced heat dissipation. This underfill is a thermal conductive material, further aiding in maintaining appropriate (e.g., optimal) operating temperatures.

In some embodiments, the semiconductor device further includes a redistribution layer, RDL 118, 1positioned below the heat conducting material, and a thermal interface material, TIM 120, placed over the plurality of chip stacks 102. This configuration aids in optimizing the thermal pathway and improving the mechanical bonding between the chip stacks and other components. The RDL can be used to create new pathways for electrical signals, effectively redistributing the I/O (input/output) pads from their locations on a die to different positions that align with the packaging requirements. RDL 118 can be made from metal layers, such as copper, which are deposited and patterned on the dielectric material that coats the semiconductor wafer. The process involves several steps including deposition of dielectric layers, photolithographic patterning, and etching, followed by metal deposition and another patterning step to create the interconnects. RDL 118 can enable finer pitch connections that are beyond the capabilities of traditional wire bonding and flip-chip techniques, and allow for a higher density of I/Os, which is critical for the increased functionality of modern microelectronic devices. RDL 118 can further help in integrating multiple dies in a single package efficiently, supporting the trend towards more compact and complex multi-die architectures.

The RDL 118 can include materials such as silicon dioxide, silicon nitride, silicon oxynitride, boron nitride, aluminum nitride, beryllium oxide, diamond, diamond-like carbon film, diamond-like carbon layer, and other thermal conducting materials with a thermal conductivity of at least 5 w/mK. These materials can be chosen for their electrical and thermal properties, supporting efficient heat dissipation and electrical isolation within the device. The heat spreader can be is composed of materials such as silicon (Si), copper (Cu), nickel (Ni), tungsten (W), molybdenum (Mo), aluminum (Al), gold (Au), platinum (Pt), palladium (Pd), or a multilayered combination of metal conductors with a thermal conductivity greater than 10 w/mK. The heat spreader can be is composed of materials such as aluminum nitride (AlN) or a multilayered combination of ceramic conductors with a thermal conductivity greater than 10 w/mK. These materials can be selected for their excellent thermal conductivity, which is crucial for managing the thermal load within the device.

TIM 120 can be used for managing the heat generated by electronic components and improve the heat dissipation from the components to the heat sink, and thus maintaining the operational temperature within safe limits. TIM 120 can be composed of various materials including greases, pastes, pads, and phase change materials. Each type has different thermal conductivity properties and application mechanisms suited for different types of devices and cooling requirements. For instance, TIM 120 can be applied between a CPU die and its heat sink to fill the microscopic air gaps that exist due to the imperfect surfaces of the die and the heat sink. This filling reduces the thermal resistance and significantly improves the heat transfer efficiency. TIM 120 can reduce of thermal resistance at the interface between the heat-generating component and the cooling device. The TIM can be included over the chip stacks to improve the heat transfer efficiency for the reliable operation of high-power and high-density semiconductor devices.

A heatsink layer, in some embodiments, is positioned over each layer of the conducting dielectric layer, which assists in heat dissipation from one side of the device. Furthermore, the heatsink is connected to both the heat spreader and the RDL, enhancing the overall heat dissipation capability of the semiconductor device.

In some embodiments, the plurality of chip stacks 102 include components such as transistors, coils, magnetic layers, decoupling capacitors, electrical conductor elements, or thermal conducting elements. In some embodiments, the semiconductor device includes functional structures such as field-effect transistors (FETs), coils, magnetic layers, decoupling capacitors, electrical conductors, and thermal conducting elements. These structures are fabricated from advanced materials, such as copper, and are integrated with additional features like heat pipes to support the electrical and thermal requirements of the device. The integration of these functional elements ensures the device operates efficiently and reliably under high-performance conditions, providing the necessary support for complex operations.

In some embodiments, the semiconductor device includes a variety of components in the chip stacks, such as transistors, coils, magnetic layers, decoupling capacitors, electrical conductor elements, or thermal conducting elements. Each of these components plays a role in the device's operation, contributing to its functionality and performance. Additionally, the power delivery structure 116 can be equipped with inductors, power delivery circuits, signal delivery circuits, electrical shielding, magnetic shielding, and cooling structures to ensure efficient power management and signal integrity throughout the device. In some embodiments, the semiconductor device includes electrical and optical communication links located within the interposer, the cooling unit, or the power feed unit. Such links facilitate the integration of advanced functionalities such as memory modules, power line pass-throughs, or signal line pass-throughs, ensuring that the semiconductor device meets the high standards required for modern electronic applications.

In some embodiments, the power delivery structure 116 within the chip stacks includes various elements such as inductors, power delivery circuits, signal delivery circuits, electrical shielding, magnetic shielding, or cooling structures. These components are integral to ensuring that the device operates efficiently, safely, and without interference from internal or external sources. The power delivery structure 116 functions as vertical power delivery chips, supplying power directly to the plurality of chip stacks while reducing (e.g., minimizing) energy losses and improving reliability. The design localizes power management to the periphery of the stack, simplifying internal routing and enabling consistent power delivery across all functional layers. The power delivery structure 116 are mounted on a substrate. The substrate is designed to be sufficiently thick, providing robust thermal conduction both laterally and vertically. To further enhance thermal performance, the substrate can incorporate active thermal management features, such as oscillating heat pipes, which efficiently transfer heat away from high-power-density regions.

In some embodiments, the power delivery structure 116 also facilitate horizontal power delivery chiplets. The horizontal power delivery structure complements the vertical power delivery system, ensuring efficient lateral distribution of power to functional layers within the chip stacks. The dual power delivery architecture reduces (e.g., minimizes) voltage drops and enhances power efficiency throughout the device. The horizontal power delivery chiplets can be integrated directly within the chip stacks, leveraging the same high thermal conductivity substrate to ensure consistent thermal and electrical performance across the device.

In some embodiments, the semiconductor device incorporates both electrical and optical communication links. These links can be located in various parts of the device such as an interposer, a cooling unit, or a power feed unit, facilitating robust and versatile connectivity for data transfer and power distribution. The communication links enable high-speed data transmission and seamless integration of electrical and optical technologies, which is important for modern semiconductor applications requiring large-scale data processing and connectivity. By incorporating both electrical and optical PHYs, the device achieves superior communication performance and supports a wide range of applications, from artificial intelligence to telecommunications. The electrical and optical communication links can be located in at least one of: an interposer, a cooling unit, or a power feed unit.

In some embodiments, at least one stack within the semiconductor device includes components such as memory units, pass-throughs of power lines, or pass-throughs of signal lines. These components are critical for enabling the device to handle complex computations, store data, and communicate efficiently within a compact, integrated structure.

In some embodiments, high bandwidth with low latency are achieved through connections less than 25 microns per layer. This configuration allows components, such as CPUs, GPUs, accelerators, and memory units, to be located in close proximity to one another. The reduced physical distance between these components reduces (e.g., minimizes) signal propagation delays and power inefficiencies, enhancing computation performance. This design is particularly advantageous for applications requiring high-speed data processing and seamless integration between multiple functional units.

In some embodiments, the chip stacks can include standard off-the-shelf or custom memory modules, as well as regular pass-throughs for power line and signal line. These features ensure compatibility with existing memory technologies while maintaining efficient and reliable power and signal flow throughout the stack. The inclusion of standard memory options allows the device to be integrated into various systems without requiring extensive customization, thereby reducing development time and costs.

In some embodiments, grounding, isolation, and shielding structures, such as Faraday cages, are incorporated into the semiconductor device based on specific application requirements. These structures protect sensitive components from electromagnetic interference, ensuring stable operation and enhancing the device's electromagnetic compatibility. By reducing (e.g., minimizing) external disturbances, these shielding mechanisms contribute to the overall reliability and performance of the semiconductor device.

In some embodiments, the semiconductor device features advanced voltage regulation designed for appropriate (e.g., optimal) power conversion and reduced voltage proximity to circuits or loads. This voltage regulation alleviates IR drops, improving the stability and efficiency of power delivery. By ensuring that power is delivered at the correct voltage levels, the device maintains consistent operation and prevents damage to sensitive components, further enhancing its reliability and lifespan.

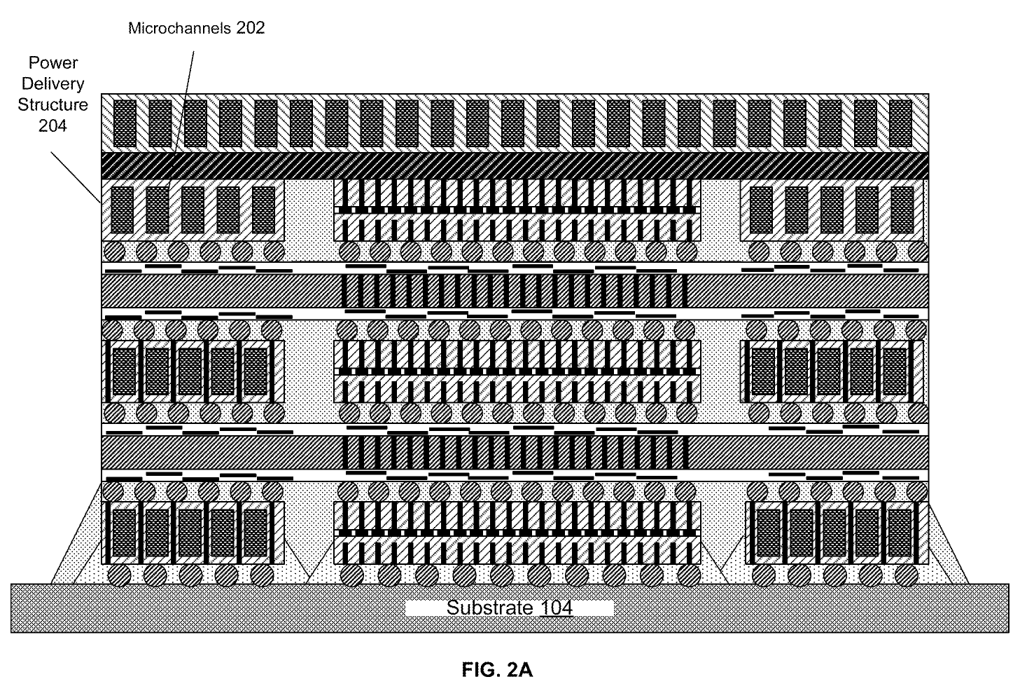

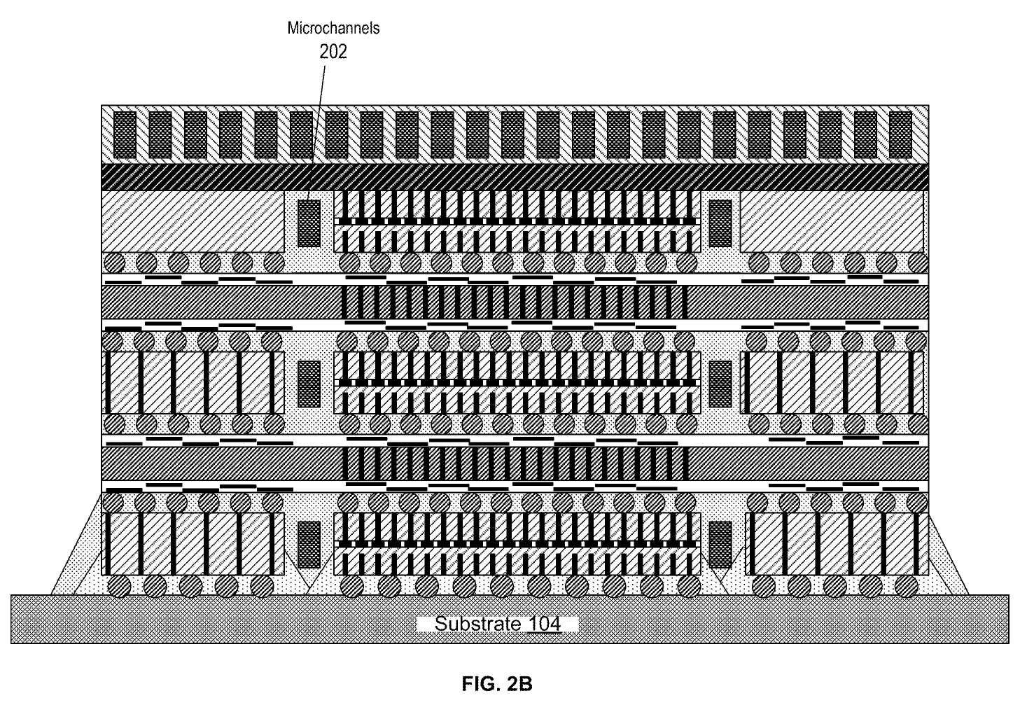

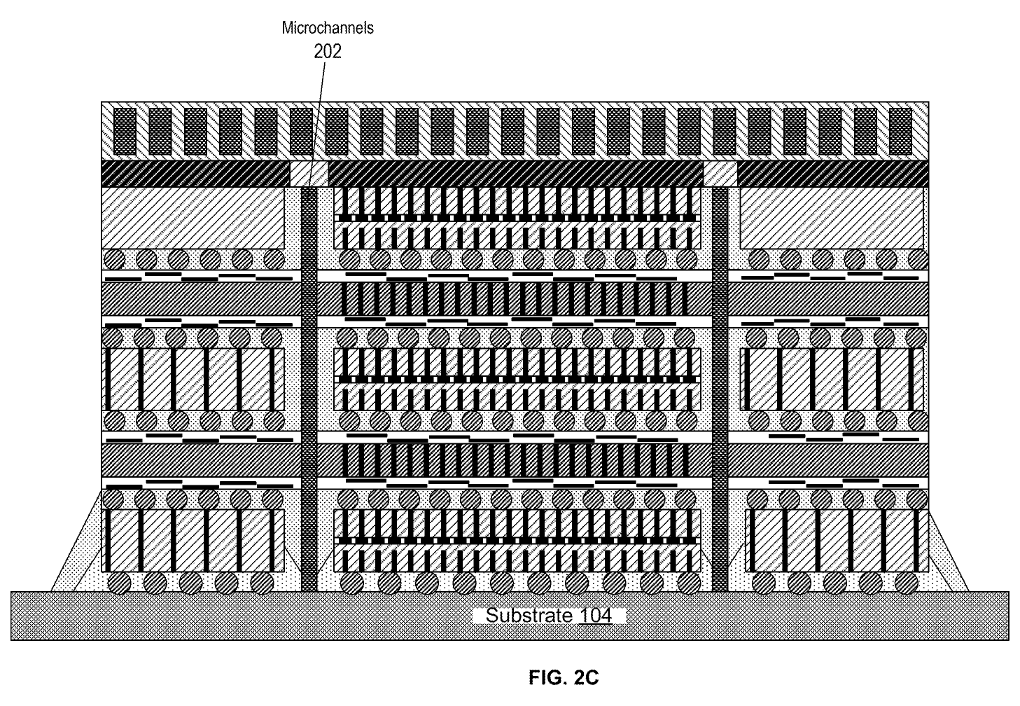

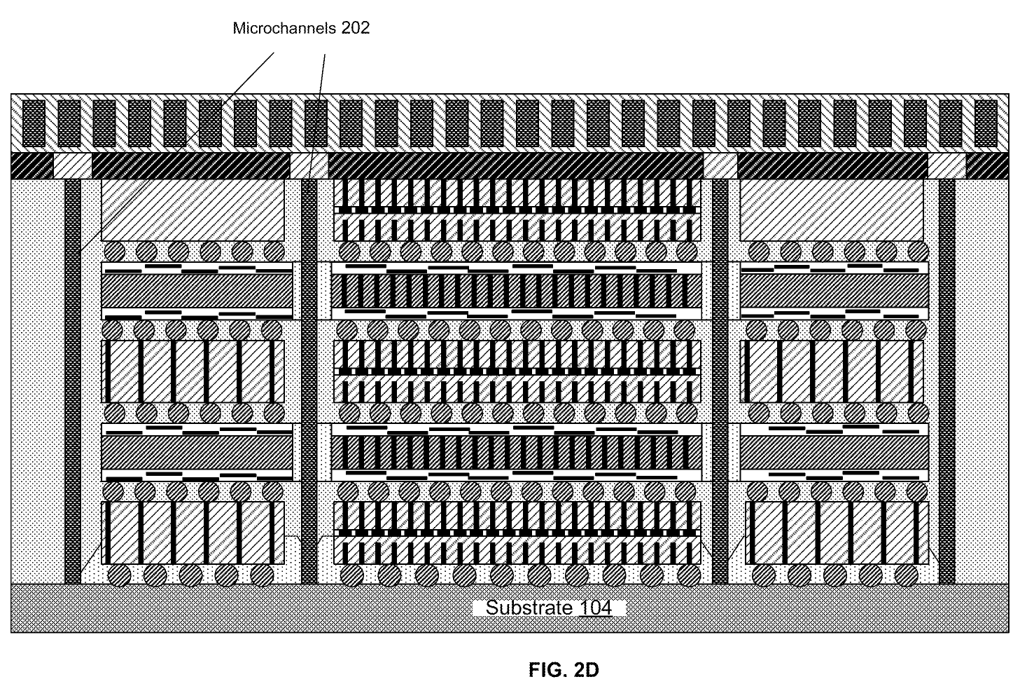

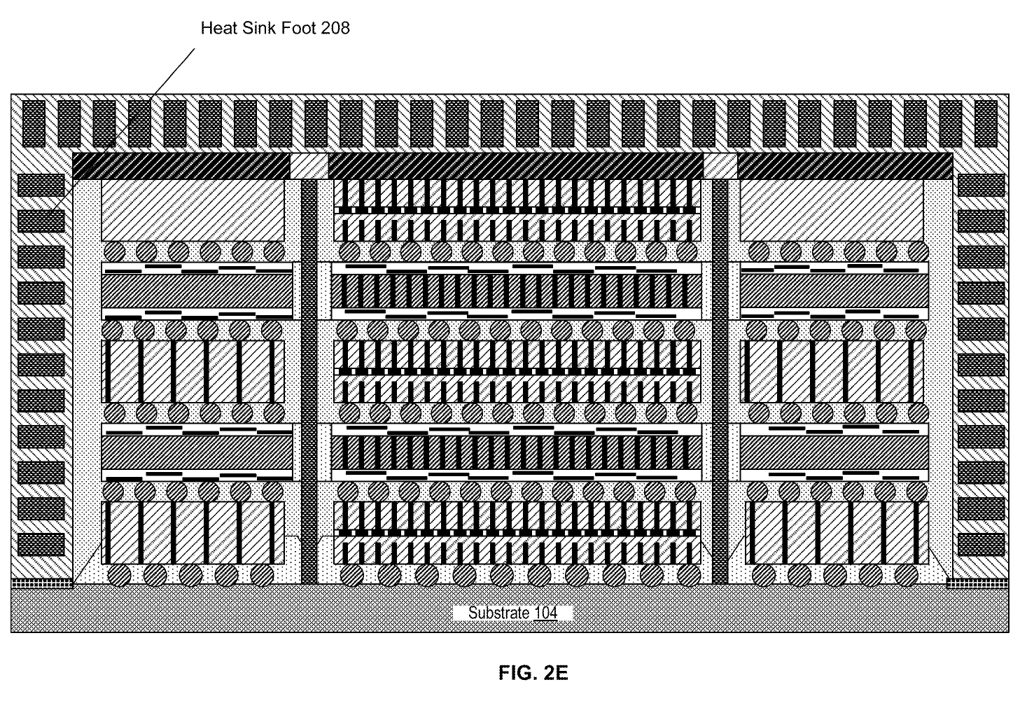

FIGS. 2A-2E illustrate a semiconductor device with microchannels in various locations. FIG. 2A illustrates the microchannels in the power delivery structures, according to some embodiments. In some embodiments, the microchannels 202 are implemented in the power delivery structure 204. In such embodiments, the cooling is performed at power delivery structure 204. FIG. 2B illustrates a semiconductor device with microchannels 202 in the side of the chips. FIG. 2C illustrates a semiconductor device with microchannels 202 in the side of the chips. The microchannels 202 are vertical and form a continuous channel. FIG. 2D illustrates a semiconductor device with microchannels 202 in the side of the power delivery structure. FIG. 2E illustrates a semiconductor device with heat sink foots 208 connected with the laminate. The microchannels can be vertical and form a continuous layer.

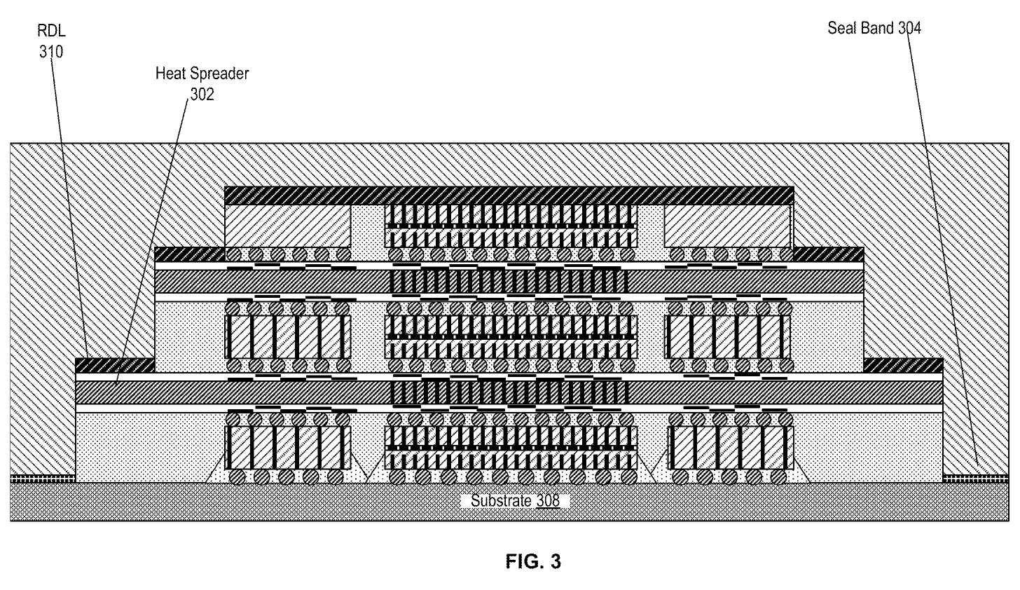

FIG. 3 illustrates a semiconductor device with heat spreader, in accordance with some embodiments. In some embodiments, a heat sink, e.g., a heat spreader 302, covers the semiconductor device. A seal band 304 isolates the laminate 308 and the heat spreader 302. The heat spreader 302 and the RDL 310 are in contact at each level.

Example Acts of Semiconductor Device with Power Delivery and Cooling for 3D Chiplet Stack Structure

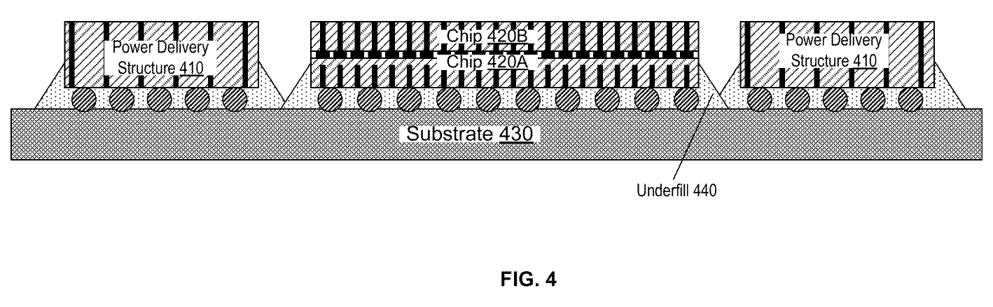

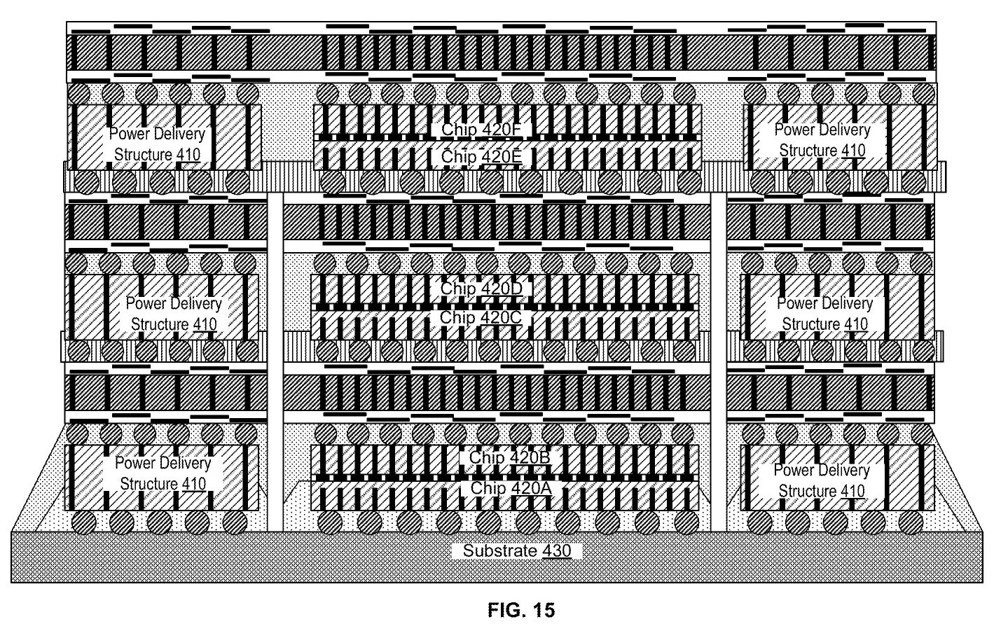

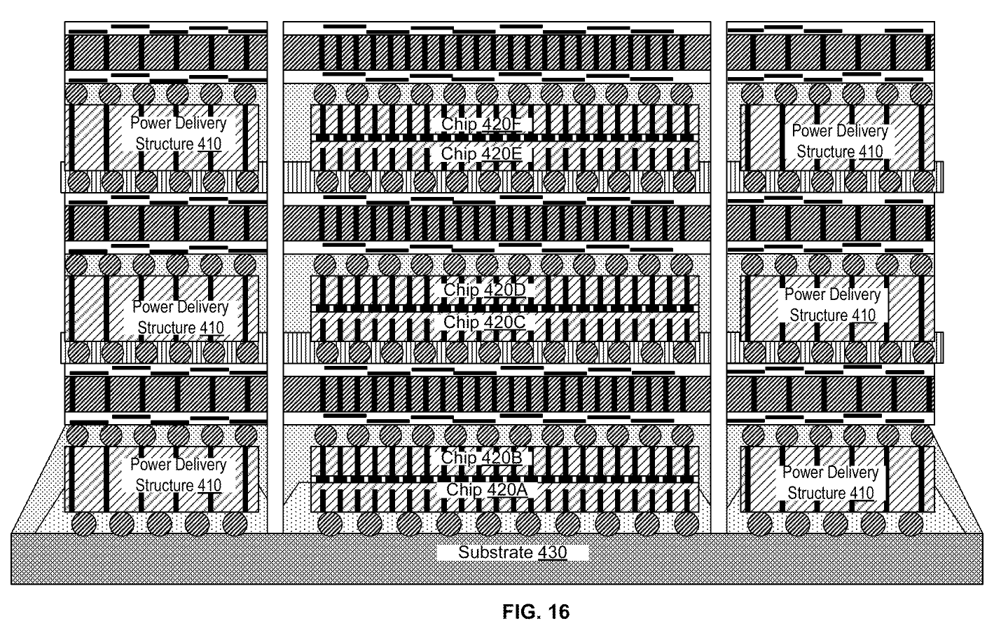

Reference now is made to FIGS. 4-17, which are simplified cross-section views of acts of fabrication of the semiconductor device. As shown in FIG. 4, in some embodiments, the semiconductor device includes power delivery structure 410 , one or more chip (e.g., 420A and 420B), a substrate 430 , and a n underfill 440 .

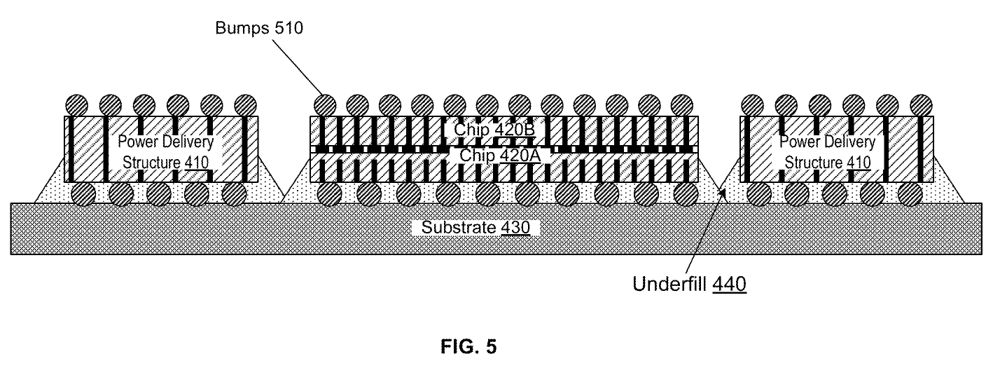

FIG. 5 illustrates the semiconductor device after bumping for the interconnect, in accordance with some embodiments. In some embodiments, bumps 510 are formed over the semiconductor device.

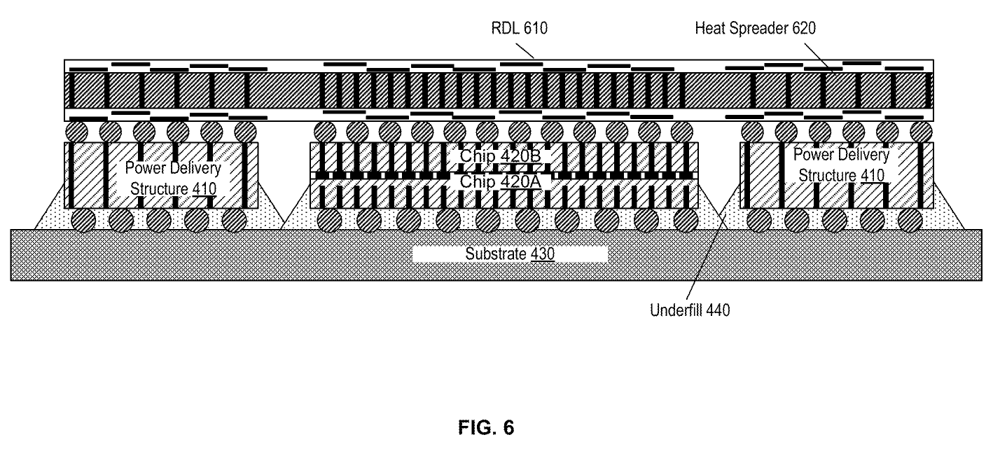

FIG. 6 illustrates the semiconductor device after assembling the heat spreader with RDL, in accordance with some embodiments. In some embodiments, the RDL 610 and the heat spreader 620 are assembled together over the semiconductor device.

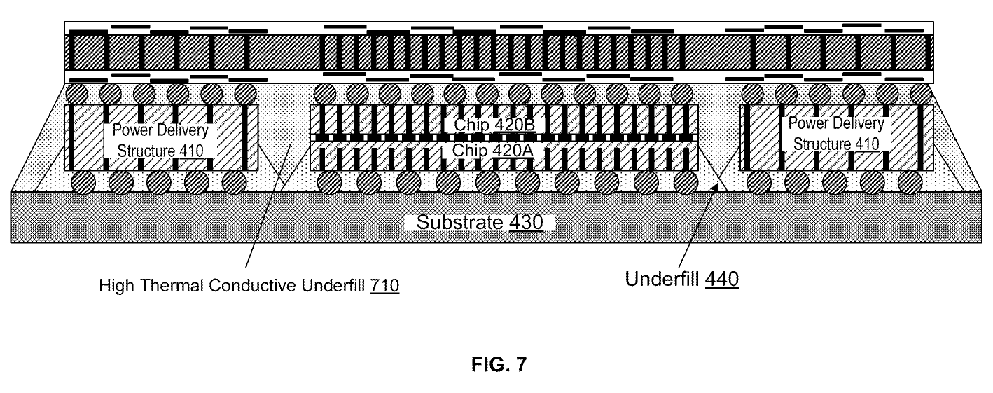

FIG. 7 illustrates the semiconductor device after the formation of the underfill, in accordance with some embodiments. In some embodiments, a high thermal conductive underfill 710 , or a molding compound, is applied over the underfill 440 .

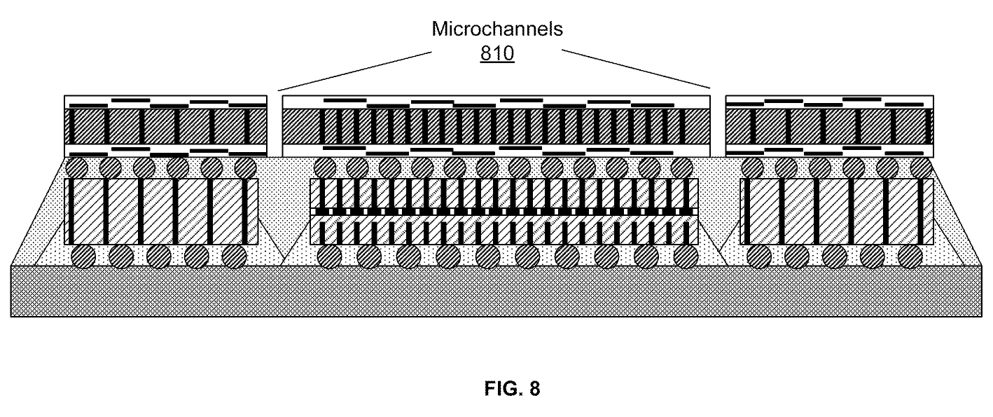

FIG. 8 illustrates the semiconductor device after forming microchannels, in accordance with some embodiments. In some embodiments, microchannels 810 are formed in the heat spreader. This can be done via a reactive ion etching (RIE) process. Reactive Ion Etching (RIE) is used to etch patterns and utilizes chemically reactive plasma to selectively remove material from the substrate, combining the physical process of sputtering with chemical reactions to achieve high-resolution etching. In RIE, a mixture of gases is introduced into a low-pressure chamber that contains the substrate. An electric field is applied to ionize the gas, creating plasma that consists of ions, electrons, and radicals. These particles are highly reactive and capable of breaking the material bonds on the substrate surface. The positive ions in the plasma are accelerated towards the substrate due to the electric field. Upon hitting the substrate, these ions physically dislodge material through momentum transfer, known as sputtering, while the radicals engage in chemical reactions with the surface, producing volatile byproducts that are vacuumed away.

The substrate can be covered with a patterned mask layer, such as photoresist, which resists the plasma. The areas exposed by the mask are etched away by the reactive ions, while the areas under the mask are protected, effectively transferring the mask pattern onto the substrate. RIE offers several advantages, including precision and anisotropy, allowing for the production of very fine, deep, and steep-sided cuts in materials. In some embodiments, a laser method, an Ar beam etching, or other directional etch methods can be used. Although, microchannels 810 shown as vertical only , horizontal layers can also be formed. In some embodiments, a liner can be formed on channel walls.

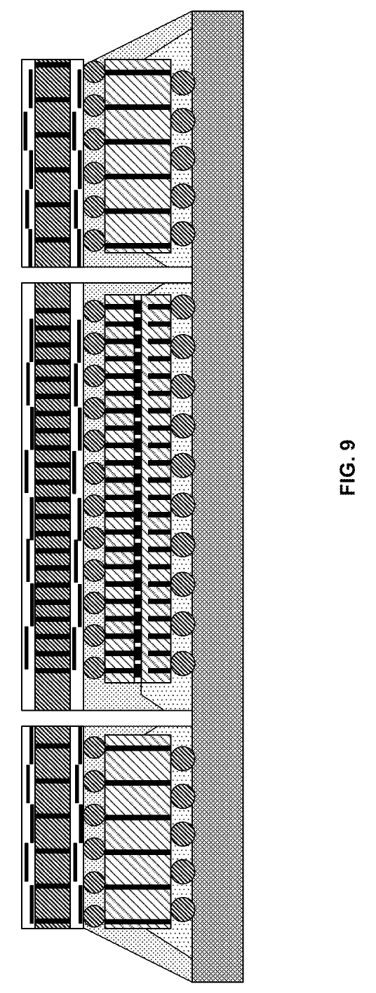

FIG. 9 illustrates the semiconductor device after forming a hole, in accordance with some embodiments. In some embodiments, a hole is formed, e.g., drilled, in the high thermal conductivity underfill or the mold.

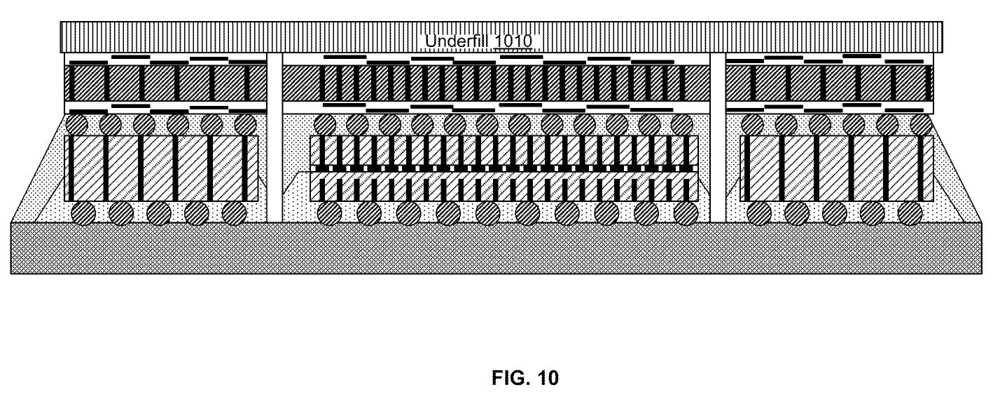

FIG. 10 illustrates the semiconductor device after formation of underfill, in accordance with some embodiments. In some embodiments, a film-type high thermal conductivity underfill, underfill 1010 , or mold is formed over the semiconductor device.

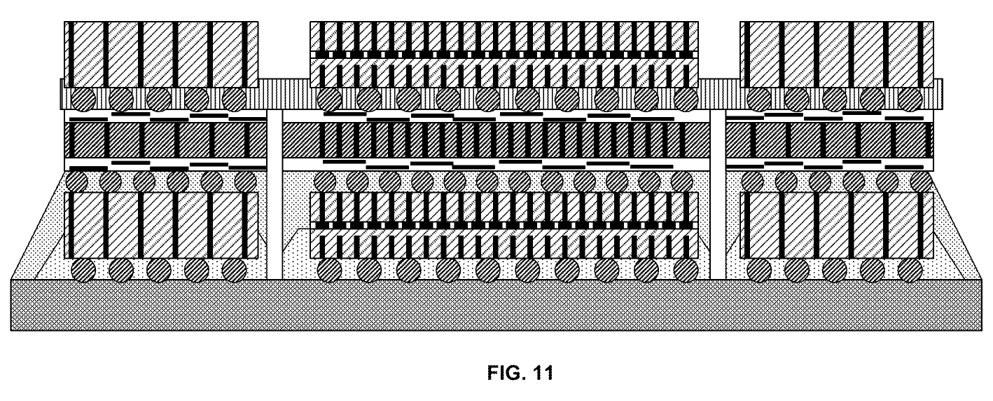

FIG. 11 illustrates the semiconductor device after assembling additional chips, in accordance with some embodiments. In some embodiments, additional chips, e.g., 3 rd and 4 th chips, are assembled. Additional power delivery structures can be assembled.

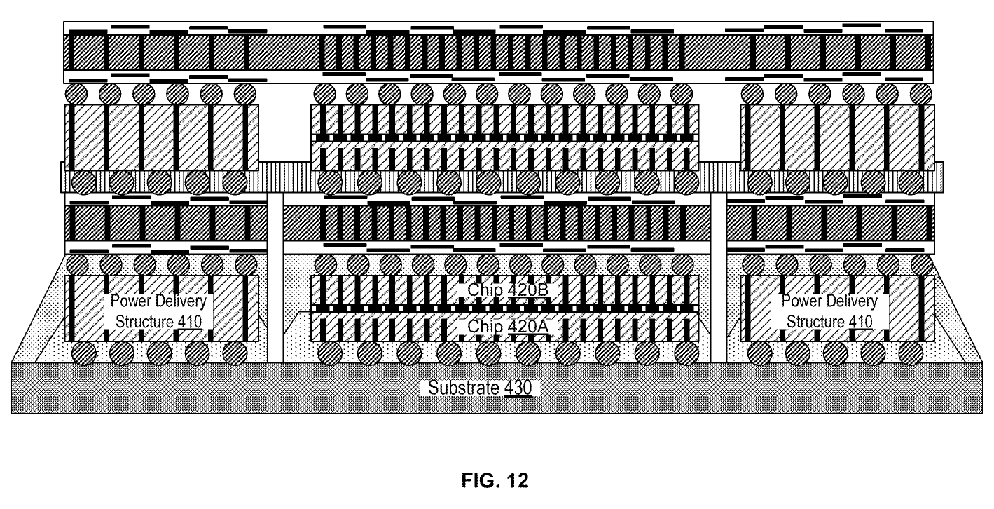

FIG. 12 illustrates the semiconductor device after assembling additional bumps, in accordance with some embodiments. In some embodiments, additional bumping for the interconnect for 3Di and power delivery structures are formed.

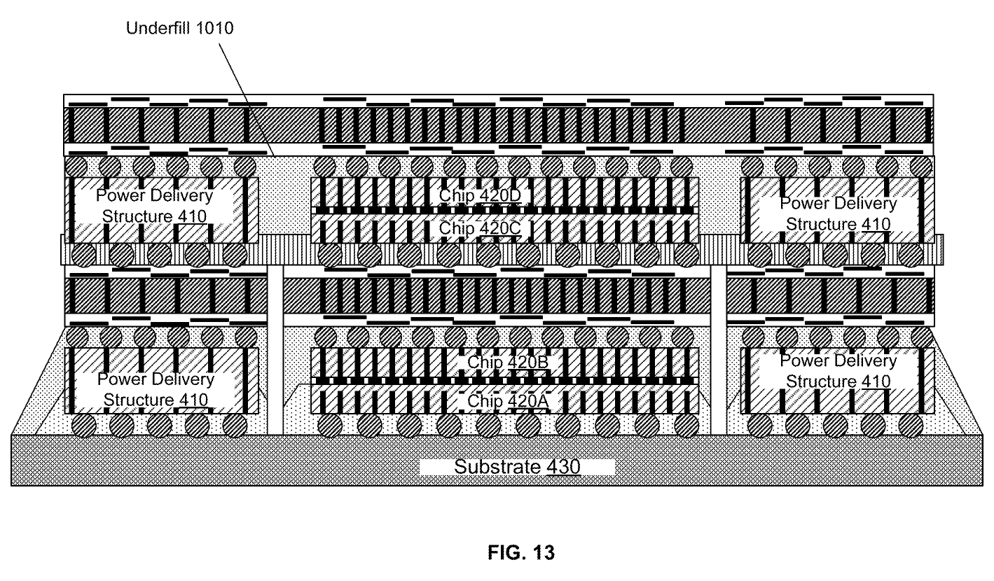

FIG. 13 illustrates the semiconductor device after formation of additional underfill, in accordance with some embodiments. In some embodiments, additional film-type high thermal conductivity underfill or mold is formed over the semiconductor device.

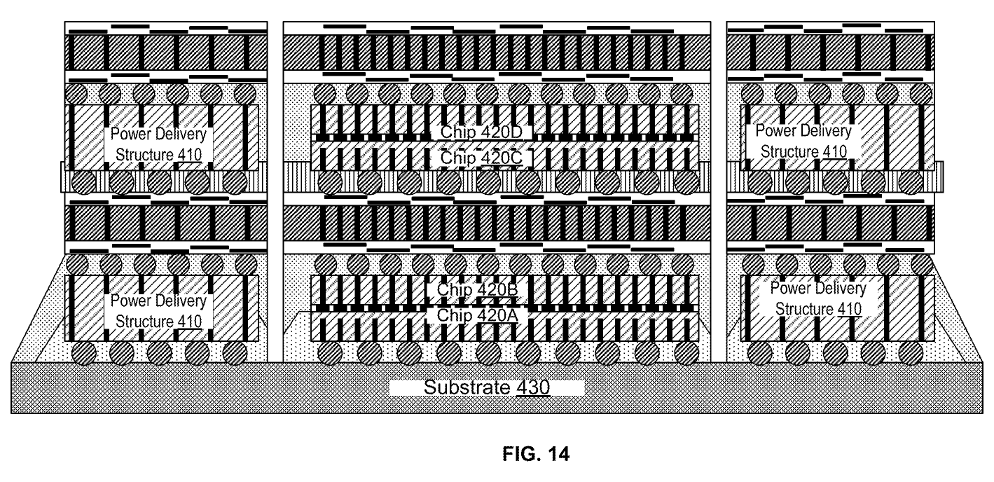

FIGS. 14-16 illustrate repeating the steps as shown in FIGS. 8-13 to fabricate the semiconductor device with the desired number of chips.

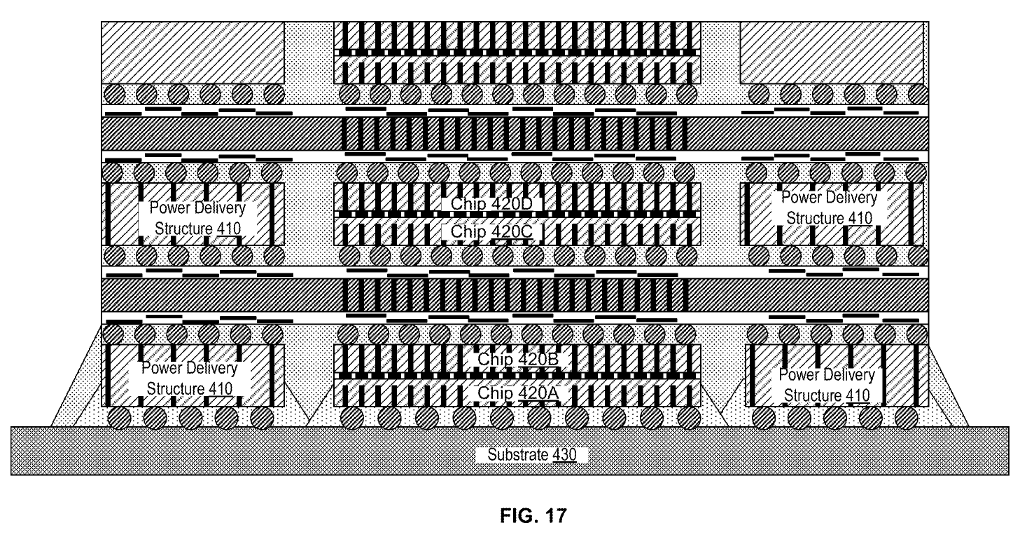

In some embodiments, after the formation of the underfill, e.g., after fabrication step according to FIG. 7, steps shown in FIGS. 4-7 are repeated. FIG. 17 illustrates the semiconductor device after repeating such steps.

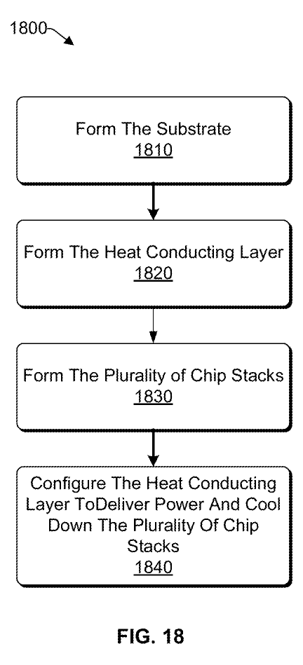

FIG. 18 illustrates a block diagram of a method 1800 for forming the semiconductor device, in accordance with some embodiments. As shown by block 1810 , a substrate is formed.

As shown by block 1820 , a heat conducting layer is formed.

As shown by block 1830, a plurality of chip stacks are formed.

As shown by block 1840, the heat conducting layer is configured to deliver power and cool down the plurality of chip stacks

In one aspect, the method and structures described above can be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip can be mounted in a single chip package (such as a plastic carrier, with leads that are affixed to a motherboard or other higher-level carrier) or in a multichip package (such as a ceramic carrier that has either or both surface interconnections or buried interconnections). In any case, the chip can then be integrated with other chips, discrete circuit elements, and/or other signal processing devices as part of either (a) an intermediate product, such as a motherboard, or (b) an end product. The end product can be any product that includes integrated circuit chips, ranging from low-end applications, such as toys, to advanced computer products having a display, a keyboard or other input device, and a central processor.

### Conclusion

The descriptions of the various embodiments of the present teachings have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to explain the principles of the embodiments, the practical application or technical improvement over technologies found in the marketplace, or to enable others of ordinary skill in the art to understand the embodiments disclosed herein.

While the foregoing has described what are considered to be the best state and/or other examples, it is understood that various modifications can be made therein and that the subject matter disclosed herein can be implemented in various forms and examples, and that the teachings can be applied in numerous applications, only some of which have been described herein. It is intended by the following claims to claim any and all applications, modifications, and variations that fall within the true scope of the present teachings.

The components, steps, features, objects, benefits, and advantages that have been discussed herein are merely illustrative. None of them, nor the discussions relating to them, are intended to limit the scope of protection. While various advantages have been discussed herein, it will be understood that not all embodiments necessarily include all advantages. Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain.

Numerous other embodiments are also contemplated. These include embodiments that have fewer, additional, and/or different components, steps, features, objects, benefits and advantages. These also include embodiments in which the components and/or steps are arranged and/or ordered differently.

While the foregoing has been described in conjunction with exemplary embodiments, it is understood that the term “exemplary” is merely meant as an example, rather than the best or optimal. Except as stated immediately above, nothing that has been stated or illustrated is intended or should be interpreted to cause a dedication of any component, step, feature, object, benefit, advantage, or equivalent to the public, regardless of whether it is or is not recited in the claims.

It will be understood that the terms and expressions used herein have the ordinary meaning as is accorded to such terms and expressions with respect to their corresponding respective areas of inquiry and study except where specific meanings have otherwise been set forth herein. Relational terms such as first and second and the like can be used solely to distinguish one entity or action from another without necessarily requiring or implying any actual relationship or order between such entities or actions. The terms “comprises,” “comprising,” or any other variation thereof, are intended to cover a non-exclusive inclusion, such that a process, method, article, or apparatus that comprises a list of elements does not include only those elements but can include other elements not expressly listed or inherent to such process, method, article, or apparatus. An element proceeded by “a” or “an” does not, without further constraints, preclude the existence of additional identical elements in the process, method, article, or apparatus that comprises the element.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments have more features than are expressly recited in each claim. Rather, as the following claims reflect, the inventive subject matter lies in less than all features of a single disclosed embodiment. Thus, the following claims are hereby incorporated into the Detailed Description, with each claim standing on its own as a separately claimed subject matter.

What is claimed is:

1. A semiconductor device, comprising:
a substrate;
a heat conducting layer comprising a redistribution layer (RDL) and a heat spreader; and
a plurality of chip stacks over the substrate and disposed in the heat conducting layer, wherein the heat conducting layer is configured to deliver power to the plurality of chip stacks and cool down the plurality of chip stacks.

2. The semiconductor device of claim 1, wherein the heat conducting layer comprises at least one of: diamond, diamond like carbon (DLC), graphite, a dielectric material, a ceramic, a metal, or a conductive film.

3. The semiconductor device of claim 1, further comprising:
at least one power delivery structure to power at least one of the plurality of chip stacks, wherein the at least one power delivery structure is located over the substrate and adjacent to the plurality of chip stacks.

4. The semiconductor device of claim 3, wherein the at least one power delivery structure further comprises at least one of: through silicon vias (TSVs), vertical connections, input/output bumps, or pillars.

5. The semiconductor device of claim 3, wherein the at least one power delivery structure is made of at least one of: Si, ceramic, Tungsten, Molybdenum, or Invar.

6. The semiconductor device of claim 3, wherein the at least one power delivery structure further comprises microchannels configured to carry a flow of heat dissipating material.

7. The semiconductor device of claim 3, wherein the at least one power delivery structure further comprises inductors, power delivery circuits, signal delivery circuits, electrical shielding, magnetic shielding, and cooling structures.

8. The semiconductor device of claim 1, further comprising a heatsink layer over the heat conducting layer.

9. The semiconductor device of claim 8, wherein the heatsink layer contacts the heat spreader and the RDL.

10. The semiconductor device of claim 1, wherein the RDL includes at least one of: silicon dioxide, silicon nitride, silicon oxynitride, boron nitride, aluminum nitride, beryllium oxide, diamond, diamond-like carbon film, diamond-like carbon layer, or a thermal conducting material with a thermal conductivity of at least 5 w/mK.

11. The semiconductor device of claim 1, wherein the heat spreader comprises at least one of: Si, Cu, Ni, W, Mo, Al, Au, Pt, Pd, or a multilayered combination of metal conductors with a thermal conductivity of greater than 10 w/MK.

12. The semiconductor device of claim 1, wherein:
the RDL is electrically connected to the substrate,
the substrate is located below one chip of the plurality of chip stacks or at a peripheral of the chip,
the substrate has a laminate structure.

13. The semiconductor device of claim 12, wherein the substrate provides ground to the plurality of chip stacks.

14. The semiconductor device of claim 1, wherein:
the semiconductor device is encapsulated with an underfill; and
the underfill is a thermal conductive material, wherein the underfill includes microchannels configured to carry a flow of heat dissipating material.

15. The semiconductor device of claim 1, further comprising a thermal interface material (TIM) over the plurality of chip stacks.

16. The semiconductor device of claim 1, wherein the plurality of chip stacks comprise at least one of: transistors, coils, magnetic layers, decoupling capacitors, electrical conductor elements, or thermal conducting elements.

17. The semiconductor device of claim 1, further comprising electrical and optical communication links, wherein:
the electrical and optical communication links are located in at least one of: an interposer, a cooling unit, or a power feed unit; and
the plurality of chip stacks comprises at least one of: a memory, a pass-throughs of power line, or a pass-through of signal line.

18. A method for fabrication of a semiconductor device, the method comprising:
forming a substrate;
forming a heat conducting layer comprising a redistribution layer (RDL) and a heat spreader;
forming a plurality of chip stacks over the substrate and disposed in the heat conducting; and
configuring the heat conducting layer to deliver power to the plurality of chip stacks and cool down the plurality of chip stacks.

19. A semiconductor device, comprising:
a plurality of chip stacks;
a power delivery interconnect chiplet surrounding one side of the plurality of chip stacks; and
a heatsink disposed on the plurality of chip stacks.

20. The semiconductor device of claim 19, wherein:
the plurality of chip stacks are disposed in a heat conducting dielectric material;
the heat conducting dielectric material includes microchannels configured to carry a flow of heat dissipating material; and
the heat dissipating material is a gas or a liquid.
